(19) United States
(12) Patent Application Publication
(10) Pub. No.: US 2015/0243597 A1
(43) Pub. Date: Aug. 27, 2015

(54) SEMICONDUCTOR DEVICE CAPABLE OF SUPPRESSING WARPING

(71) Applicant: INOTERA MEMORIES, INC., Taoyuan (TW)

(72) Inventors: Hsu Chiang, New Taipei City (TW); Yaw-Wen Hu, Taoyuan County (TW)

(73) Assignee: INOTERA MEMORIES, INC., Taoyuan (TW)

(21) Appl. No.: 14/190,025

(22) Filed: Feb. 25, 2014

(51) Int. Cl. H01L 23/528; H01L 23/00; H01L 23/31; H01L 23/29; H01L 23/498; B81B 7/00

(52) U.S. Cl. CPC H01L 23/528; H01L 23/49838; B81B 7/0006; H01L 23/3171; H01L 23/291; H01L 23/562

(57) ABSTRACT

A semiconductor device includes a substrate having a front side and a rear side, a plurality of dielectric layers on the front side, a plurality of interconnection circuit structures in the dielectric layers, and at least one backside passivation layer on the rear side. The backside passivation layer and the top passivation layer are made of the same material and have substantially the same thickness.

### BACKGROUND OF THE INVENTION

1. Field of the Invention

The present invention relates to a semiconductor device in which wafer warping is suppressed. 2. Description of the Prior Art

Semiconductor manufacturing and packaging technology has evolved to the point where device packages can include multiple integrated circuit chips in a stacked relationship in order to provide a smaller form factor and higher integration density at the package level.

It is known in the art that a silicon thinning process is usually performed on the back surface of wafers for thinning the wafers. However, after performing the silicon thinning process and prior to the final packaging process, wafer or die warpage may occur. The wafer or die warpage may cause yield loss and reliability issues.

### SUMMARY OF THE INVENTION

One object of the present invention is to provide a semiconductor device in which a semiconductor wafer is less likely to warp.

According to one embodiment, a semiconductor device includes a substrate having a front side and a rear side, a plurality of dielectric layers on the front side, a plurality of interconnection circuit structures in the dielectric layers, and at least one backside passivation layer on the rear side. The backside passivation layer and the top passivation layer are made of the same material and have substantially the same thickness.

According to one embodiment, the top passivation layer comprises silicon nitride, silicon oxy-nitride, or polyimide.

According to one embodiment, the backside passivation layer comprises silicon nitride, silicon oxy-nitride, or polyimide.

According to one embodiment, the substrate has a thickness ranging between 50 micrometers and 150 micrometers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 is a schematic, cross-sectional diagram showing a substrate after the bulk of the wafer was thinned by surface-grinding, wherein substrate warping is shown; and

FIG. 2 is a schematic, cross-sectional diagram showing a substrate after the bulk of the wafer was thinned by surface-grinding according to one embodiment of the invention, wherein the substrate warping is suppressed.

It should be noted that all the figures are diagrammatic. Relative dimensions and proportions of parts of the drawings are exaggerated or reduced in size, for the sake of clarity and convenience. The same reference signs are generally used to refer to corresponding or similar features in modified and different embodiments.

### DETAILED DESCRIPTION

In the following description, numerous specific details are given to provide a thorough understanding of the invention. It will, however, be apparent to one skilled in the art that the invention may be practiced without these specific details. Furthermore, some well-known system configurations and process steps are not disclosed in detail, as these should be well-known to those skilled in the art.

Likewise, the drawings showing embodiments of the apparatus are semi-diagrammatic and not to scale and some dimensions are exaggerated in the figures for clarity of presentation. Also, where multiple embodiments are disclosed and described as having some features in common, like or similar features will usually be described with like reference numerals for ease of illustration and description thereof.

The terms wafer and substrate used herein include any structure having an exposed surface onto which a layer is deposited according to the present invention, for example, to form the integrated circuit (IC) structure. The term substrate is understood to include semiconductor wafers. The term substrate is also used to refer to semiconductor structures during processing, and may include other layers that have been fabricated thereupon. Both wafer and substrate include doped and undoped semiconductors, epitaxial semiconductor layers supported by a base semiconductor or insulator, as well as other semiconductor structures well known to one skilled in the art.

The following detailed description is, therefore, not to be taken in a limiting sense, and the scope of the present invention is defined only by the appended claims, along with the full scope of equivalents to which such claims are entitled.

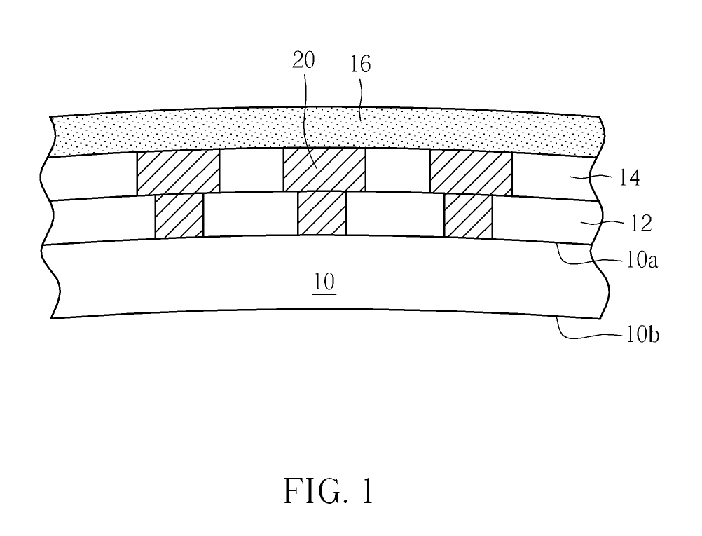

FIG. 1 is a schematic, cross-sectional diagram showing a substrate after the bulk of the wafer was thinned by surface-grinding. As shown in FIG. 1, a substrate 10 such as a silicon substrate, a semiconductor substrate, an interposer substrate, a 3-dimentional (3D) integrated circuit (IC) substrate, or a MEMS (Micro Electro Mechanical System) substrate is provided. The substrate 10 has a front side 10a and a rear side 10b. On the front side 10a, a plurality of dielectric layers 12, 14 and a plurality of interconnection circuit structures 120 in the dielectric layers 12, 14 are formed. A top passivation layer 16 such as a silicon nitride layer or silicon oxy-nitride layer is typically coated overlying the dielectric layers 12, 14 and the interconnection circuit structures 120.

The bulk of the substrate 10 was thinned by surface-grinding on the rear side 10b. After thinning by surface-grinding, the remaining thickness of the substrate 10 may range between 50 micrometers and 150 micrometers. Because of the tensile (or compressive) stress imparted from the top passivation layer 16, the substrate warpage may occur. The substrate warpage may cause step height between wafer center and wafer edge, resulting in yield loss and reliability issues during or after the final packaging process.

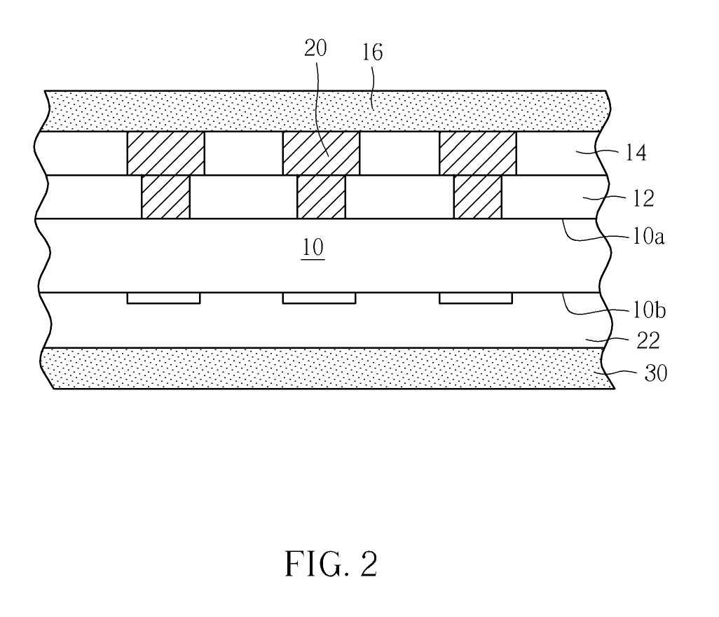

FIG. 2 is a schematic, cross-sectional diagram showing a substrate after the bulk of the wafer was thinned by surface-grinding according to one embodiment of the invention. As shown in FIG. 2, likewise, a substrate 10 such as a silicon substrate, a semiconductor substrate, an interposer substrate, a 3D IC substrate, or a MEMS substrate is provided. The substrate 10 has a front side 10a and a rear side 10b. On the front side 10a, a plurality of dielectric layers 12, 14 and a plurality of interconnection circuit structures 120 in the dielectric layers 12, 14 are formed. A top passivation layer 16 such as a silicon nitride layer, silicon oxy-nitride layer, or polyinide is typically coated overlying the dielectric layers 12, 14 and the interconnection circuit structures 120.

The bulk of the substrate 10 was thinned by surface-grinding on the rear side 10b. After thinning by surface-grinding, the remaining thickness of the substrate 10 may range between 30 micrometers and 200 micrometers. As mentioned above, the tensile (or compressive) stress imparted from the top passivation layer 16 causes the substrate warpage. To suppress the warping, according to the embodiment, a backside passivation layer 30 is coated overlying the rear side 10b of the substrate 10 after the bulk of the wafer was thinned by surface-grinding. Optionally, at least one interlayer dielectric film 22 is provided between the backside passivation layer 30 and the rear side 10b of the substrate 10. If necessary, an interconnection structure (not shown) may be formed within the at least one interlayer dielectric film 22.

According to the embodiment, the backside passivation layer 30 and the top passivation layer 16 are made of the same material and have substantially the same thickness. For example, the backside passivation layer 30 and the top passivation layer 16 are made of silicon nitride, silicon oxy-nitride, or polyimide. According to the embodiment, the backside passivation layer 30 and the top passivation layer 16 are the topmost layer on the rear side 10b and the front side 10a respectively, prior to the final packaging process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate having a front side and a rear side;
a plurality of dielectric layers on the front side;
a plurality of interconnection circuit structures in the dielectric layers; and
at least one backside passivation layer on the rear side.

2. The semiconductor device according to claim 1 wherein the substrate comprises a silicon substrate.

3. The semiconductor device according to claim 1 wherein the substrate comprises a semiconductor substrate.

4. The semiconductor device according to claim 1 wherein the substrate comprises an interposer substrate.

5. The semiconductor device according to claim 1 wherein the substrate comprises a 3-dimentional integrated circuit substrate.

6. The semiconductor device according to claim 1 wherein the substrate comprises a Micro Electro Mechanical System (MEMS) substrate.

7. The semiconductor device according to claim 1 wherein the backside passivation layer and the top passivation layer are made of the same material and have substantially the same thickness.

8. The semiconductor device according to claim 1 wherein the top passivation layer comprises silicon nitride, silicon oxy-nitride, or polyimide.

9. The semiconductor device according to claim 1 wherein the backside passivation layer comprises silicon nitride, silicon oxy-nitride, or polyimide.

10. The semiconductor device according to claim 1 wherein the substrate has a thickness ranging between 30 micrometers and 200 micrometers.

11. The semiconductor device according to claim 1 further comprising an interlayer dielectric film between the backside passivation layer and the rear side of the substrate.
